(19) United States
(12) Patent Application Publication
(10) Pub. No.: US 2026/0235670 A1
(43) Pub. Date: Aug. 13, 2026

(54) DUAL-MODE CHIP DETERMINING OPERATION MODE ACCORDING TO BONDING WIRE CONNECTION

(71) Applicant: PIXART IMAGING INC., Hsin-Chu County (TW)

(72) Inventors: Chun-Yuan CHIU, Hsin-Chu County (TW); Chia-Pei CHEN, Hsin-Chu County (TW); Jheng-Liang CHEN, Hsin-Chu County (TW); Chia-Chi CHENG, Hsin-Chu County (TW)

(21) Appl. No.: 19/052,286

(22) Filed: Feb. 13, 2025

(51) Int. Cl. G01R 31/317; G01R 1/04

(52) U.S. Cl. CPC G01R 31/31706; G01R 1/0416

(57) ABSTRACT

There is provided a dual-mode chip including two bonding pads and a differential detection circuit. When only one of the two bonding pads is connected to a voltage source, the differential detection circuit detects a non-zero differential signal and outputs a first mode signal to control the dual-mode chip to enter a first mode. When both of the two bonding pads are connected to the voltage source, the differential detection circuit detects a zero differential signal and outputs a second mode signal to control the dual-mode chip to enter a second mode.

### FIELD OF THE DISCLOSURE

This disclosure generally relates to a dual-mode chip and, more particularly, to a dual-mode chip that determines an operation mode thereof according to bonding wire connections of two bonding pads of the dual-mode chip with a power source, and an operating method of the dual-mode chip.

### BACKGROUND OF THE DISCLOSURE

The low dropout voltage regulator (LDO) is generally used to provide a stable core voltage. It is known that some integrated circuits have a LDO circuit that can provide two output voltages, so called dual-mode LDO circuit. Said two output voltages are used to provide downstream circuits requiring different voltages.

The dual-mode LDO circuit may be controlled by a digital circuit therein to select one LDO voltage to be outputted.

However, before the digital circuit of the dual-mode LDO circuit is activated (e.g., just power up), the digital circuit is not able to know whether a high voltage or a low voltage is required to be provided by the dual-mode LDO circuit. Therefore, if a voltage provided by a top-level power source of the dual-mode LDO circuit is not correct, e.g., the dual-mode LDO circuit for providing low core voltage but the top-level system power providing high voltage, the circuit damage could be induced.

In addition, the dual-mode LDO circuit generally requires two LDO circuits and ESD pads that occupy large circuit space.

Therefore, it is required a dual-mode chip that can determine an output voltage in an analog phase before a digital circuit is activated.

The information disclosed in this BACKGROUND is merely intended to increase understanding of the general background of the invention and should not be taken as an admission or in any way implied that the relevant information constitutes prior art that is already known to a person of ordinary skill in the art.

### SUMMARY

Accordingly, the present disclosure provides a dual-mode chip that shares a part of circuits to save circuit space, and an operating method of the dual-mode chip.

The present disclosure further provides a dual-mode chip that controls an operation mode of a dual-mode circuit according to a mode signal determined by the analog voltage input, and an operating method of the dual-mode chip.

The present disclosure provides a dual-mode chip including a first bonding pad, a second bonding pad and a differential detection circuit. The first bonding pad is configured to be connected to a voltage source via a first bonding wire. The differential detection circuit is configured to detect a voltage difference between the first bonding pad and the second bonding pad. When the voltage difference is not zero due to the second bonding pad being floated, the differential detection circuit is configured to output a first mode signal. When the voltage difference is equal to zero due to the second bonding pad being connected to the voltage source via a second bonding wire, the differential detection circuit is configured to output a second mode signal.

The present disclosure further provides a dual-mode chip including a first bonding pad, a second bonding pad, a differential detection circuit, a first downstream circuit and a second downstream circuit. The differential detection circuit is electrically connected to the first bonding pad and the second bonding pad, and configured to detect a differential signal between the first bonding pad and the second bonding pad, output a first mode signal upon the differential signal not zero, and output a second mode signal upon the differential signal equal to zero. The first downstream circuit is configured to be enabled upon the differential detection circuit outputting the first mode signal. The second downstream circuit is configured to be enabled upon the differential detection circuit outputting the second mode signal.

The present disclosure further provides an operating method of a dual-mode chip, which includes a first bonding pad connected to a voltage source, a second bonding pad, a differential detection circuit and a dual-mode circuit. The operating method includes the steps of: detecting, using the differential detection circuit, a voltage difference between the first bonding pad and the second bonding pad; outputting, by the differential detection circuit, a first mode signal to control the dual-mode circuit to operate in a first mode upon the voltage difference not zero; and outputting, by the differential detection circuit, a second mode signal to control the dual-mode circuit to operate in a second mode upon the voltage difference equal to zero.

### BRIEF DESCRIPTION OF DRAWINGS

Other objects, advantages, and novel features of the present disclosure will become more apparent from the following detailed description when taken in conjunction with the accompanying drawings.

FIG. 1 is a circuit diagram of a chip package of a dual-mode chip arranged on a substrate according to one embodiment of the present disclosure.

FIG. 2 is a schematic block diagram of a dual-mode chip according to one embodiment of the present disclosure.

FIG. 3 is a schematic block diagram of a dual-mode circuit of a dual-mode chip according to one embodiment of the present disclosure.

FIG. 4A is an operational schematic diagram of a differential detection circuit of a dual-mode chip operating in a first mode according to one embodiment of the present disclosure.

FIG. 4B is an operational schematic diagram of a differential detection circuit of a dual-mode chip operating in a second mode according to one embodiment of the present disclosure.

FIG. 5 is a flow chart of an operating method of a dual-mode chip according to one embodiment of the present disclosure.

FIG. 6 is a schematic diagram of a multi-mode chip according to another embodiment of the present disclosure.

### DETAILED DESCRIPTION OF THE DISCLOSURE

It should be noted that, wherever possible, the same reference numbers will be used throughout the drawings to refer to the same or like parts.

One objective of the present disclosure is to provide a dual-mode chip that determines an operation mode according to whether two bonding pads thereof are physically connected to a power source (e.g., analog power source) via the bonding wire, and an operating method of the dual-mode chip. In the present disclosure, the operation modes of the dual-mode chip include enabling different downstream circuits, outputting different voltage values, normal and sleep modes, but not limited thereto.

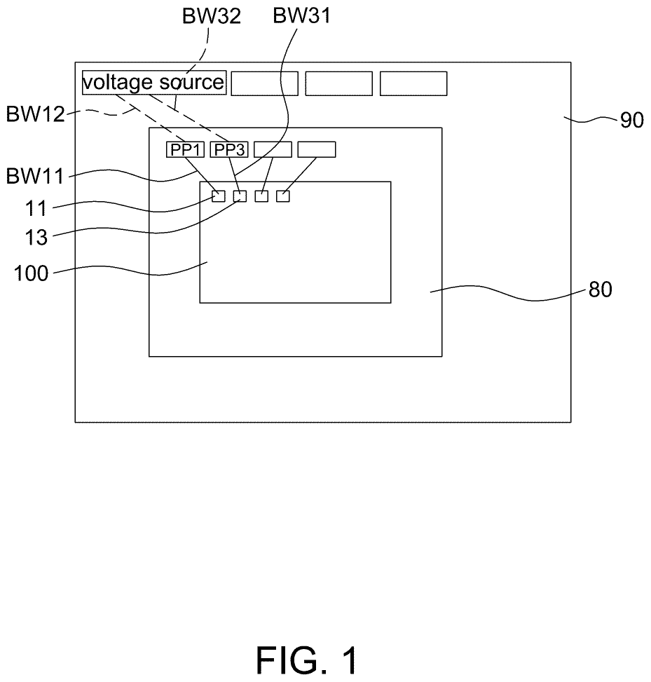

Please refer to FIG. 1, it is a schematic diagram of a chip package of a dual-mode chip 100 (e.g., bare die) arranged on a substrate 90 according to one embodiment of the present disclosure. FIG. 1 shows that the dual-mode chip 100 is firstly arranged on a carrier board 80, and after packaging process, the chip package is arranged on a substrate 90. The type of the substrate 90 is not particularly limited as long as it is able to carry the chip package and provide the system voltage source, e.g., a film substrate, a hard board, a flexible board,.

FIG. 1 shows that the first bonding pad 11 of the dual-mode chip 100 is connected to a power pad PP1 of the carrier board 80 via a bonding wire BW11, and the power pad PP1 is connected to a voltage source via a bonding wire BW12. The second bonding pad 13 of the dual-mode chip 100 is connected to a power pad PP3 of the carrier board 80 via a bonding wire BW31, and the power pad PP3 is connected to the voltage source via a bonding wire BW32. In the present disclosure, the voltage source is preferably a fixed system voltage source, e.g., voltage source providing 3-5 volts which is determined according to a system voltage required by the dual-mode chip 100. The voltage source is preferably arranged on the substrate 90. The arrangement of the voltage source is not limited to that shown in FIG. 1, and the voltage source may be provided at one side or multiple sides of the substrate 90 depending on different applications thereof.

It should be mentioned that although FIG. 1 shows that the first bonding pad 11 is connected to the voltage source sequentially via the bonding wire BW11 and BW12, and the second bonding wire 13 is connected to the voltage source sequentially via the bonding wire BW31 and BW32, they are only intended to show that the first bonding pad 11 and the second bonding pad 13 are used to be connected to the voltage source via bonding wires. In one aspect, the dual-mode chip of the present disclosure is a bare die including the first bonding pad 11 and the second bonding pad 13, and the dual-mode chip is not limited to include a further bonding wire connecting to the first bonding pad 11 and the second bonding pad 13, respectively. In another aspect, the dual-mode chip of the present disclosure is a chip package including power pads PP1 and PP3, and inside the chip package there is a bonding wire BW11 connecting between the first bonding pad 11 and the power pad PP1 as well as a bonding pad BW31 connecting between the second bonding pad 13 and the power pad PP3, and the dual-mode chip is not limited to include bonding wires BW12 and BW32 connecting to the power pads PP1 and PP3, respectively. The bonding wires BW12 and BW32 are used when the chip package is electrically connected to the substrate 90.

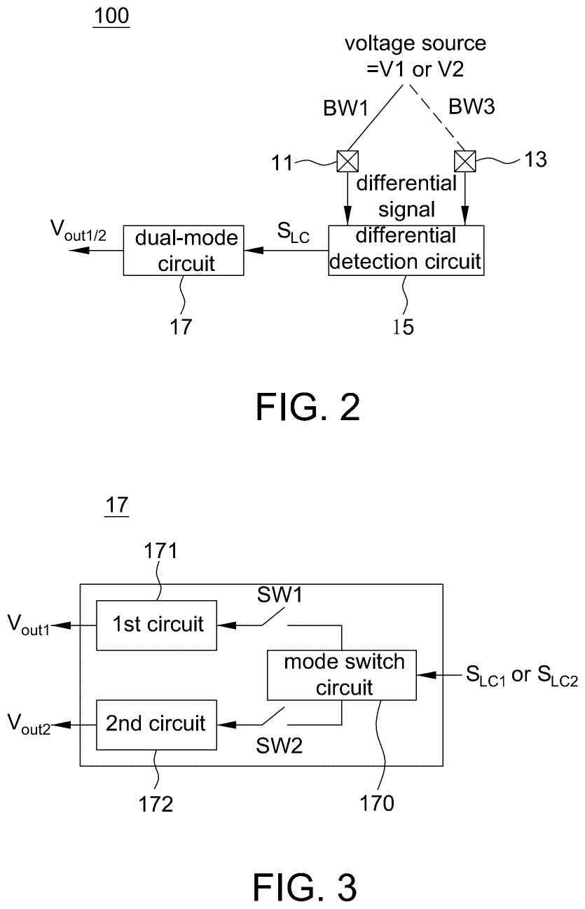

Please refer to FIGS. 2 and 3, FIG. 2 is a schematic block diagram of a dual-mode chip 100 according to one embodiment of the present disclosure; and FIG. 3 is a schematic block diagram of a dual-mode circuit 17 of a dual-mode chip 100 according to one embodiment of the present disclosure. The dual-mode chip 100 includes a first bonding pad 11, a second bonding pad 13, a differential detection circuit 15 and a dual-mode circuit 17. In the present disclosure, the dual-mode circuit 17 is not particularly limited as long as having two operation modes (or circuits) and being able to be switched to one of the operation modes (or circuits) according to a mode signal S_{LC} outputted by the differential detection circuit 15.

The differential detection circuit 15 is electrically connected (accomplished during the semiconductor manufacturing process) to the first bonding pad 11 and the second bonding pad 13, and is used to detect a differential signal, e.g., a voltage difference or current difference, between the first bonding pad 11 and the second bonding pad 13. As mentioned above, the first bonding pad 11 is connected to the voltage source via first bonding wires BW11 and BW13.

In one aspect, when the second bonding pad 13 is floated to cause the voltage difference or the current difference is not zero, the differential detection circuit 15 outputs a first mode signal S_{LC1} (e.g., “1” or “0”). When the second bonding wire 13 is connected to the voltage source via second bonding wires BW31 and BW32 to cause the voltage difference or the current difference is equal to zero (i.e. two bonding pads connected to the same voltage source), the differential detection circuit 15 outputs a second mode signal S_{LC2} (e.g., “0” or “1”).

It is appreciated that when the dual-mode chip 100 is implemented as a chip package, the first bonding pad 11 is replaced by the power pad PP1, and the second bonding pad 13 is replaced by the power pad PP3.

In one aspect, the dual-mode circuit 17 includes a mode switching circuit 170, a first downstream circuit (e.g., abbreviated as first circuit for simplification) 171, a second downstream circuit (abbreviated as second circuit for simplification) 172. After receiving the first mode signal S_{LC1} or the second mode signal S_{LC2}, the mode switching circuit 170 enables the first circuit 171 or the second circuit 172 via the switching device SW1 or SW2 (e.g., a transistor switch).

It should be mentioned that the switching device SW1 is not limited to one and not limited to be between the first circuit 171 and the mode switching circuit 170. The mode switching device 170 may switch more than one switching devices, inside and/or outside the first circuit 171, to accomplish the mode switching. The switching device SW2 is not limited to one and not limited to be between the second circuit 172 and the mode switching circuit 170. The mode switching device 170 may switch more than one switching devices, inside and/or outside the second circuit 172, to accomplish the mode switching.

In one aspect, the mode switching circuit 170 controls the operation mode of the dual-mode circuit 17 only according to the mode signal S_{LC} without according to any other signal from a digital circuit of the dual-mode chip 100.

For example, the dual-mode circuit 17 is connected downstream of the differential detection circuit 15. The first circuit 171 is enabled when the differential detection circuit 15 outputs a first mode signal S_{LC1}; and the second circuit 172 is enabled when the differential detection circuit 15 outputs a second mode signal S_{LC2}. In the present disclosure, when the first circuit 171 is activated, the second circuit 172 is turned off; on the contrary, when the second circuit 172 is enabled, the first circuit 171 is turned off.

In the present disclosure, when only one of the first bonding pad 11 and the second bonding pad 13 (taking the first bonding pad 11 as an example) is connected to a first voltage source V1, the differential signal is not zero; and when both of the first bonding pad 11 and the second bonding pad 13 are connected to a second voltage source V2 (the same one), the differential signal is equal to zero. In one aspect, the first voltage source V1 has a voltage higher than that of the second voltage source V2, but not limited to. Values of the first voltage V1 and the second voltage V2 are determined according to requirements of the first mode and the second mode. As mentioned above, the first voltage V1 and the second voltage V2 are fixed system voltages external to the dual-mode chip 100, and preferably provided by the substrate 90.

In one aspect, the first circuit 171 is a universal serial bus (USB) LDO circuit; and the second circuit 172 is a mobile industry processor interface (MIPI) LDO circuit. That is, the dual-mode chip 100 is a dual-mode LDO chip. The dual-mode LDO chip is used to operate in a USB mode after receiving the first mode signal S_{LC1} and to output a first voltage Vout1, e.g., 3.3 volts; and the dual-mode LDO chip is used to operate in a MIPI mode after receiving the second mode signal S_{LC2} and to output a second voltage Vout2, e.g., 2.5 volts. It is appreciated that when the dual-mode LDO chip is operated in other different modes, values of the first voltage Vout1 and the second voltage Vout2 may be set as other values. In other aspects, the first circuit 171 and the second circuit 172 are arranged to output different currents according to applications thereof, and are not limited to output different voltages.

In addition, the dual-mode circuit 17 may require different system voltages in different operation modes. In one aspect, when the first bonding pad 11 is connected to the voltage source via first bonding wires (e.g., BW11 and BW12), and the second bonding pad 13 is floated, the voltage source has a first voltage V1. When the first bonding pad 11 is connected to the voltage source via first bonding wires (e.g., BW11 and BW12), and the second bonding pad 13 is connected to the voltage source via second bonding wires (e.g., BW31 and BW32), the voltage source has a second voltage V2, which is different from the first voltage V1. For example, the first voltage V1 and the second voltage V2 are system voltages provided by different substrates.

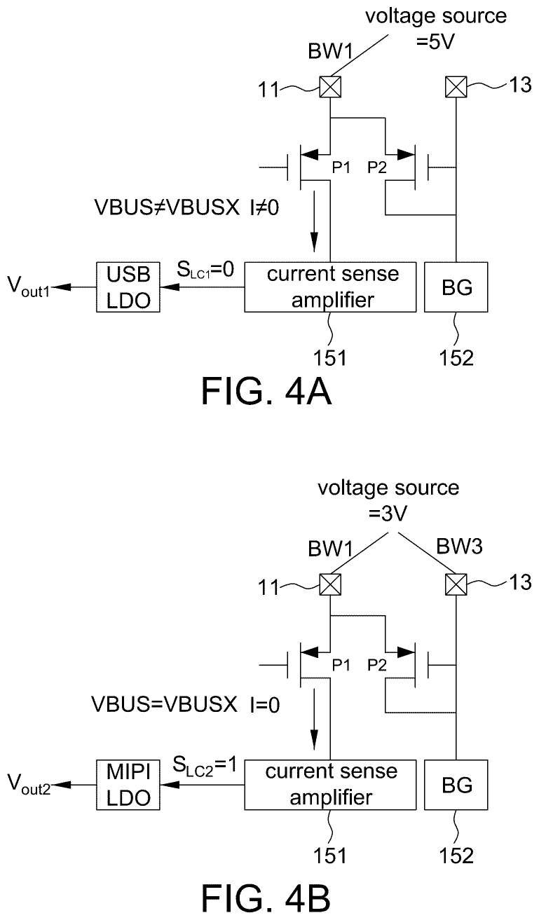

Please refer to FIGS. 4A and 4B, FIG. 4A is an operational schematic diagram of a differential detection circuit 15 of a dual-mode chip 100 operating in a first mode according to one embodiment of the present disclosure; and FIG. 4B is an operational schematic diagram of a differential detection circuit 15 of a dual-mode chip 100 operating in a second mode according to one embodiment of the present disclosure. In this embodiment, a dual-mode LDO chip is taken as an example for illustrating the dual-mode chip 100.

In one aspect, the differential detection circuit 15 includes a current sense amplifier 151, a bandgap circuit (shown as BG) 152, a first PMOS transistor P1 and a second PMOS transistor P2. The first PMOS transistor P1 is connected between the first bonding pad 11 and the current sense amplifier 151. The second PMOS transistor P2 is connected between the first bonding pad 11, the second bonding pad 11 and the bandgap circuit 152. The current sense amplifier 151 is used to sense an input current I from the first PMOS transistor P1 as a way to detect the voltage difference.

As shown in FIG. 4A, when the first bonding pad 11 is connected to a 5 volts voltage source via a bonding wire BW1 and the second bonding pad 13 is floated, the current sense amplifier 151 outputs a first mode signal S_{LC1}=0 because the input current I is not zero, and the dual-mode circuit 17 enters a USB mode to output a first voltage Vout1. As shown in FIG. 4B, when the first bonding pad 11 and the second bonding pad 13 are connected to a 3 volts voltage source respectively via bonding wires BW1 and BW3, the current sense amplifier 151 outputs a second mode signal S_{LC2}=1 because the input current I is equal to zero, and the dual-mode circuit 17 enters a MIPI mode to output a second voltage Vout2. It is appreciated that S_{LC1} may be set as 1 and S_{LC2} may be set as 0, and they are not limited to those mentioned herein.

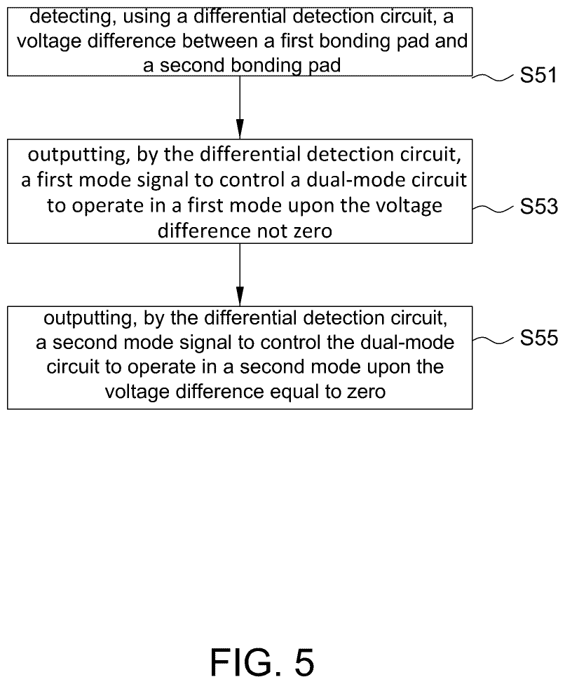

Please refer to FIG. 5, it is a flow chart of an operating method of a dual-mode chip 100 according to one embodiment of the present disclosure. As shown in FIG. 2, the dual-mode chip 100 includes a first bonding pad 11 connected to a voltage source, a second bonding pad 13, a differential detection circuit 15 and a dual-mode circuit 17. The operating method includes the steps of: detecting, using the differential detection circuit 15, a voltage difference between the first bonding pad 11 and the second bonding pad 13 (Step S51); outputting, by the differential detection circuit 15, a first mode signal S_{LC1} to control the dual-mode circuit 17 to operate in a first mode upon the voltage difference not zero (Step S53); and outputting, by the differential detection circuit 15, a second mode signal S_{LC2} to control the dual-mode circuit 17 to operate in a second mode upon the voltage difference equal to zero (Step S55). As mentioned above, the voltage difference is detected by sensing a current value by a current sense amplifier 151.

The method that the differential detection circuit 15 detects a voltage difference between the first bonding pad 11 and the second bonding pad 13 and a circuit of the differential detection circuit 15 are not limited to those mentioned in the present disclosure.

Since the differential detection circuit 15 of the present disclosure outputs the first mode signal S_{LC1} or the second mode signal S_{LC2} before the dual-mode circuit 17 is activated, a voltage required by the downstream circuit (i.e. the dual-mode circuit 17) in operation is correctly provided to avoid damaging circuit components.

In addition, since different mode circuits share the bandgap circuit and bonding pads, the occupied circuit area is reduced and the usable number of bonding pads is increased.

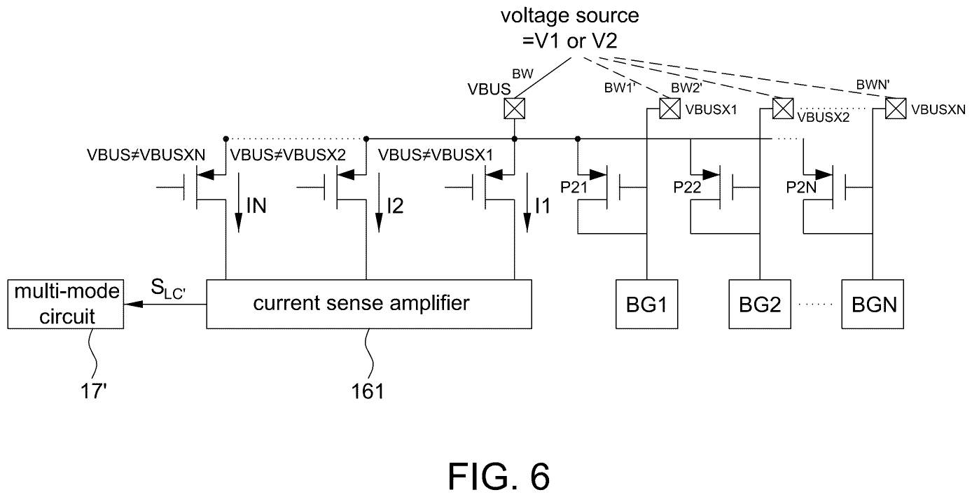

It should be mentioned that although the above embodiments are described in the way that the differential detection circuit 15 outputs a one-bit mode signal, the present disclosure is not limited thereto. In the aspect that the dual-mode circuit 17 is replaced by a multi-mode circuit (i.e. more than two operable functions or modes), the differential detection circuit is implemented by FIG. 6 as an example.

In FIG. 6, multiple PMOS transistors are connected between a current sense amplifier 161 and a first bonding pad VBUS, one PMOS transistor P21 is connected between a first bandgap circuit (e.g., shown as BG1) and a second bonding pad VBUSX1, one PMOS transistor P22 is connected between a second bandgap circuit (e.g., shown as BG2) and a third bonding pad VBUSX2 ... one PMOS transistor P2N is connected between an Nth bandgap circuit (e.g., shown as BGN) and an (N+1)th bonding pad VBUSXN.

Similarly, the first bonding pad VBUS is used to be physically connected to a voltage source (e.g., shown as V1 or V2) via a bonding wire BW. When the second bonding pad VBUSX1 is floated, a current I1 is not zero, and when the second bonding pad VBUSX1 is physically connected to the voltage source via a bonding wire BW1′, the current I1 is equal to 0. When the third bonding pad VBUSX2 is floated, a current I2 is not zero, and when the third bonding pad VBUSX2 is physically connected to the voltage source via a bonding wire BW2′, the current I2 is equal to 0. When the (N+1)th bonding pad VBUSXN is floated, a current IN is not zero, and when the (N+1)th bonding pad VBUSXN is physically connected to the voltage source via a bonding wire BWN', the current IN is equal to 0. In this case, the current sense amplifier 161 outputs multi-bits (e.g., N bits) mode signal S_{LC}′ to the multi-mode circuit 17′ to control the multi-mode circuit 17′ to operate in one of multiple modes or functions.

It should be mentioned that values, e.g., voltage values and digital values, mentioned in the present disclosure are only intended to illustrate but not to limit the present disclosure.

As mentioned above, before a digital circuit of a dual-mode LDO circuit begins to operate, the digital circuit is unable to control the dual-mode LDO to switch at the top system level such that an issue of damaging the circuit components may be induced. Accordingly, the present disclosure further provides a dual-mode chip that determines an operation mode of a dual-mode circuit according to analog voltage input (e.g., FIGS. 2-3) and an operating method thereof (e.g., FIG. 5) that determine a digital value (“0” or “1”) according to an analog voltage prior to activation of a digital circuit according to whether bonding pads of the dual-mode chip are connected to a system voltage via bonding wires to receive the analog voltage. The digital value is used to determine an operation mode of the dual-mode circuit.

Although the disclosure has been explained in relation to its preferred embodiment, it is not used to limit the disclosure. It is to be understood that many other possible modifications and variations can be made by those skilled in the art without departing from the spirit and scope of the disclosure as hereinafter claimed.

1. A dual-mode chip, comprising:
a first bonding pad, configured to be connected to a voltage source via a first bonding wire;
a second bonding pad; and
a differential detection circuit, configured to detect a voltage difference between the first bonding pad and the second bonding pad, wherein
when the voltage difference is not zero due to the second bonding pad being floated, the differential detection circuit is configured to output a first mode signal, and
when the voltage difference is equal to zero due to the second bonding pad being connected to the voltage source via a second bonding wire, the differential detection circuit is configured to output a second mode signal.

2. The dual-mode chip as claimed in claim 1, wherein the dual-mode chip is a dual-mode low dropout voltage regulator (LDO) chip.

3. The dual-mode chip as claimed in claim 2, further comprising an LDO circuit connected downstream of the differential detection circuit, wherein the LDO circuit is configured to
output a first voltage upon receiving the first mode signal, and
output a second voltage, different from the first voltage, upon receiving the second mode signal.

4. The dual-mode chip as claimed in claim 2, wherein the LDO circuit is configured to
operate in a universal serial bus (USB) mode upon receiving the first mode signal, and
operate in a mobile industry processor interface (MIPI) mode upon receiving the second mode signal.

5. The dual-mode chip as claimed in claim 1, wherein the voltage source is a fixed system voltage source.

6. The dual-mode chip as claimed in claim 1, wherein
the voltage source has a first voltage upon the first bonding pad being connected to the voltage source via the first bonding wire and the second bonding pad being floated,
the voltage source has a second voltage upon the first bonding pad being connected to the voltage source via the first bonding wire and the second bonding pad being connected to the voltage source via the second bonding wire, and
the first voltage is different from the second voltage.

7. The dual-mode chip as claimed in claim 1, wherein the power source is arranged on a substrate.

8. The dual-mode chip as claimed in claim 1, wherein the differential detection circuit comprises:
a current sense amplifier;
a bandgap circuit; and
a first PMOS transistor, connected between the first bonding pad and the current sense amplifier; and
a second PMOS transistor, connected between the first bonding pad, the second bonding pad and the bandgap circuit,
wherein the current sense amplifier is configured to sense an input current from the first PMOS transistor to detect the voltage difference.

9. A dual-mode chip, comprising:
a first bonding pad;
a second bonding pad;
a differential detection circuit, electrically connected to the first bonding pad and the second bonding pad, and configured to
detect a differential signal between the first bonding pad and the second bonding pad,
output a first mode signal upon the differential signal not zero, and
output a second mode signal upon the differential signal equal to zero;
a first downstream circuit, configured to be enabled upon the differential detection circuit outputting the first mode signal; and
a second downstream circuit, configured to be enabled upon the differential detection circuit outputting the second mode signal.

10. The dual-mode chip as claimed in claim 9, wherein the first downstream circuit is a USB LDO circuit, and the second downstream circuit is a MIPI LDO circuit.

11. The dual-mode chip as claimed in claim 9, wherein
the differential signal is not zero upon only one of the first bonding pad and the second bonding pad being connected to a first voltage source, and
the differential signal is equal to zero upon both the first bonding pad and the second bonding pad being connected to a second voltage source.

12. The dual-mode chip as claimed in claim 11, wherein the first voltage source has a voltage higher than that of the second voltage source.

13. The dual-mode chip as claimed in claim 11, wherein the first voltage source and the second voltage source are fixed system voltage outside the dual-mode chip.

14. The dual-mode chip as claimed in claim 9, wherein the differential detection circuit comprises:
a current sense amplifier;
a bandgap circuit; and
a first PMOS transistor, connected between the first bonding pad and the current sense amplifier; and
a second PMOS transistor, connected between the first bonding pad, the second bonding pad and the bandgap circuit,
wherein the current sense amplifier is configured to sense an input current from the first PMOS transistor as the differential signal.

15. An operating method of a dual-mode chip, the dual-mode chip comprising a first bonding pad connected to a voltage source, a second bonding pad, a differential detection circuit and a dual-mode circuit, the operating method comprising:
detecting, using the differential detection circuit, a voltage difference between the first bonding pad and the second bonding pad;
outputting, by the differential detection circuit, a first mode signal to control the dual-mode circuit to operate in a first mode upon the voltage difference not zero; and
outputting, by the differential detection circuit, a second mode signal to control the dual-mode circuit to operate in a second mode upon the voltage difference equal to zero.

16. The operating method as claimed in claim 15, wherein
the differential detection circuit outputting the first mode signal indicates that the second bonding pad is floated, and
the differential detection circuit outputting the second mode signal indicates that the second bonding pad and the first bonding pad are both connected to the voltage source.

17. The operating method as claimed in claim 15, further comprising:
outputting a first voltage by the dual-mode circuit in the first mode; and
outputting a second voltage, different from the first voltage, by the dual-mode circuit in the second mode.

18. The operating method as claimed in claim 15, wherein the voltage source is a fixed system voltage source.

19. The operating method as claimed in claim 15, wherein the first bonding pad is connected to the voltage source via a first bonding wire.

20. The operating method as claimed in claim 15, wherein the differential detection circuit outputs the first mode signal or the second mode signal before the dual-mode circuit is activated.
